(19) United States
(12) Patent Application Publication
(10) Pub. No.: US 2026/0106110 A1
(43) Pub. Date: Apr. 16, 2026

(54) System and Method for Enhanced Atomic Layer Etching Process for High Aspect Ratio Structures

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/914,268

(22) Filed: Oct. 14, 2024

(51) Int. Cl. H01J 37/32

(52) U.S. Cl. CPC H01J 37/32128; H01J 37/32146; H01J 37/32816; H01J 2237/24585; H01J 2237/3341; H01J 2237/338

(57) ABSTRACT

Disclosed is a method and system for atomic layer etching (ALE) that utilizes a single gas or mixed gases throughout the process without gas exchanges. The ALE process involves a continuous surface modification process, where the substrate surface undergoes chemical alteration, followed by intermittent ion-burst sputtering steps to remove the modified surface. The process eliminates undesired reactive ion etching (RIE), achieving an ideal ALE process through the use of a novel bias unit design. The disclosed method and system are particularly suitable for forming high aspect ratio (HAR) structures.

### FIELD OF THE INVENTION

The present invention pertains to the field of semiconductor manufacturing, more specifically to atomic layer etching (ALE) techniques used in semiconductor device fabrication. The invention focuses on optimizing the ALE process by utilizing a single gas or a single gas mixture throughout the ALE process and designing process parameters to improve the ideality of the ALE process.

### BACKGROUND OF THE INVENTION

ALE has been developed to address the limitations of Reactive Ion Etching (RIE), a widely used technique for material removal in semiconductor fabrication. Although RIE provides high etch rates and can handle a variety of materials, it suffers from significant drawbacks, particularly when applied to high aspect ratio (HAR) structures. These limitations include profile distortion and non-uniform etching. As semiconductor devices become more advanced, with increasing demands for smaller feature sizes and higher aspect ratios, these issues become more pronounced.

ALE offers a solution to these problems by enabling precise, atomic-scale material removal through sequential, self-limiting reactions. The ALE process typically comprises two steps: surface modification and material removal. During the surface modification step, chemically reactive neutrals—often generated in a plasma—modify the surface layer of the substrate, typically reducing the bond energy of a few monolayers. This step is followed by low-energy ion bombardment that removes the modified layer without damaging the underlying substrate. This sequence is repeated in cycles to achieve controlled, atomic-level etching.

While ALE provides significant advantages over RIE in terms of precision and selectivity, it presents its own set of challenges. The cyclic nature of ALE, with separate surface modification and material removal steps, inherently limits the etch rate, making it problematic for HAR structures where etch speed is critical. Conventional ALE processes often require gas exchanges between the surface modification and material removal steps, increasing cycle time and process complexity.

A key challenge in ALE is the control of ion energy during the sputtering step. In conventional ALE systems, substrate bias is applied using an RF power generator, which accelerates ions toward the substrate to remove the modified layer. However, RF power generators typically require tens of milliseconds to achieve the desired steady-state bias voltage. This delay can result in low speed for the removal step. Achieving rapidly consistent ion energy and a small angular distribution is crucial for maintaining vertical sidewalls and avoiding profile distortions, such as bowing.

Furthermore, ALE has not been widely adopted for etching deep HAR structures, such as channel holes in 3D NAND devices, primarily due to its slower etch rate. As 3D NAND devices continue to increase in complexity, with stacks now exceeding 200 pairs of oxide and nitride layers, the challenges of etching these structures have intensified. Common issues include slow etch rates, difficulty in delivering ions to the bottom of deep structures, and profile distortions such as bowing.

In addition, existing ALE processes often struggle to achieve high synergy between the surface modification and sputtering steps. Ideally, the two steps should complement each other, maximizing the overall etch per cycle (EPC) with minimal unwanted etching from either step. In practice, it is difficult to prevent ions from causing some etching during the surface modification step, while physical sputtering during the removal step may affect unmodified material, reducing the ideality of the ALE process. Karanik et al., in their paper “Predicting synergy in atomic layer etching” (J. Vac. Sci. Technol. A35, 2017), emphasized the importance of minimizing unwanted etching from both steps to maximize process efficiency.

One approach to mitigating these challenges, as disclosed in U.S. Pat. No. 9,362,131 to Agarwal et al., involves using a remote plasma source combined with an electron beam to minimize ion energy during surface modification. While this method reduces the risk of reactive ion etching (RIE) during surface modification, it requires additional equipment, adding complexity and cost. Another method, described in U.S. Pat. No. 10,763,083 to Yang et al., employs high-energy ions to accelerate the removal of the modified layer.

Recent advancements, such as pulsing the RF power applied to the substrate for more precise ion energy control (as described in WO Pat. Pub. No. 2023/183129), aim to improve ALE processes. However, these methods often require complex control systems and frequent adjustments to gas flow rates and valve positions, further complicating the process and limiting throughput in high-volume manufacturing.

In light of these challenges, the present invention introduces novel ALE methods and systems to enhance process efficiency and precision, offering a more effective solution for etching HAR structures.

### SUMMARY OF THE INVENTION

The present invention addresses the aforementioned challenges by introducing an innovative ALE process that eliminates the need for gas exchanges between surface modification and sputtering steps, thereby significantly reducing cycle time and simplifying process control. Instead of relying on RF power generators that require a substantial time to establish a steady-state substrate bias, the invention utilizes a tailored waveform generator to establish the bias in microseconds, enabling rapid ion-burst sputtering with minimal re-modification of the surface.

The process is characterized by continuous surface modification throughout the entire ALE process, with ion-burst sputtering steps inserted intermittently. The duration of each sputtering step is carefully controlled to ensure minimal surface re-modification during ion-burst sputtering step.

The tailored waveform generator ensures precise control over ion energy, maintaining vertical sidewalls in HAR structures, which is critical for etching features such as those found in 3D NAND and DRAM devices. By addressing the limitations of conventional ALE processes, the invention offers a more efficient solution for precisely etching HAR structures in advanced semiconductor manufacturing. The use of a single gas or gas mixture, combined with rapid ion-burst sputtering, improves process speed, uniformity, and selectivity, making ALE a more practical option for HAR structure formation.

In some embodiments, the present invention relates to a method and system for ALE that employs a single gas or gas mixture throughout the process, enhancing efficiency and reducing cycle time. The invention eliminates the need for gas exchanges between surface modification and sputtering steps, streamlining the etching process and improving throughput.

In some implementations, the ALE process comprises a continuous surface modification step, wherein chemically reactive neutrals modify the surface of the substrate. This modification occurs throughout the process, ensuring that a consistently modified surface layer is available prior to material removal. The invention further includes multiple ion-burst sputtering steps, wherein ions are accelerated toward the substrate using a tailored waveform generator. This tailored waveform allows for precise control of ion energy, enabling rapid and selective removal of the modified surface layer while preventing unwanted RIE.

In some embodiments, the system includes a controller that manages the operation of a switch, alternating between grounding the substrate during surface modification and applying the tailored waveform during sputtering. This system ensures that during surface modification, the substrate remains grounded to minimize ion bombardment. During sputtering step, the tailored waveform provides controlled ion bursts to remove the modified layer without re-modification of the surface.

In some implementations, the tailored waveform generator provides a substrate bias in microseconds, enabling short bursts of ions to remove the modified layer without allowing sufficient time for further surface modification.

In some embodiments, the system is particularly useful for etching HAR structures, such as those found in 3D NAND and DRAM devices. The use of a single gas or gas mixture throughout the ALE process, combined with the tailored waveform generator, offers significant advantages in terms of etch uniformity, vertical profile control, and reduced risk of profile distortion. This invention enhances both the efficiency and precision of ALE, making it highly suitable for advanced semiconductor manufacturing.

### BRIEF DESCRIPTIONS OF THE DRAWINGS

To provide enhanced clarity, the following description references the accompanying drawings:

FIG. 1 illustrates an exemplary process system for a novel ALE process featuring continuous surface modification with intermittent ion-burst sputtering steps.

FIG. 2 depicts the waveforms of the plasma source, substrate bias, and gases used in the ALE process.

FIG. 3 shows a schematic diagram of the ALE process applied to ONON etching for 3D NAND channels, with continuous surface modification and intermittent ion-burst sputtering steps.

FIG. 4 presents a flowchart of the ALE process according to one embodiment.

### DETAILED DESCRIPTION

To ensure comprehensive understanding, this section delves into detailed embodiments of the present invention. Although certain specifics are provided for clarity, modifications and variations that align with the subsequent claims are deemed appropriate. Conventional methods and components are highlighted to underscore the distinct features of the invention.

### Definitions

Atomic Layer Etching (ALE): A precise, layer-by-layer material removal process typically used in semiconductor fabrication. ALE involves alternating steps, often surface modification followed by physical removal (such as sputtering), to achieve atomic-level control over material etching. The self-limiting reactions in each cycle ensure high selectivity and precision.

Process Chamber: A sealed environment where a range of manufacturing processes, such as etching, deposition, or chemical treatments, occur. The chamber is designed to hold a substrate and maintain a controlled environment, which may include vacuum conditions, temperature regulation, and the introduction of gases or plasma to facilitate the process.

High Aspect Ratio (HAR) Structures: Structures characterized by a large ratio of height to width (or depth to width). These features are common in advanced manufacturing, particularly in microelectronics and semiconductor devices, where components like 3D NAND or DRAM require precise vertical etching to create deep, narrow features without collapsing or distorting the structure.

Surface Modification: A process in which the surface of a material is chemically or physically altered to achieve specific characteristics. This can involve the application of reactive species to form a modified layer, which may be easier to remove, bond to, or otherwise manipulate in subsequent steps.

Sputtering Step: A process in which atoms are ejected from a solid material due to the impact of energetic particles, typically ions. In etching, the sputtering step selectively removes surface layers by bombarding the material with ions to physically dislodge atoms or molecules from the surface.

Neutral: Electrically neutral particles, such as atoms or molecules, that do not carry a net charge. These particles can still participate in chemical reactions but do not contribute to direct ion bombardment or electrical interactions with the substrate. Neutrals are important in plasma processes as they can diffuse into regions where charged particles cannot reach.

Chemically Reactive Neutrals: Neutral particles that are chemically active and capable of reacting with a substrate's surface. These neutrals do not have a charge but can still modify the surface by forming bonds or altering the chemical structure, making subsequent material removal easier or more controlled.

Ion-Burst: A brief, controlled release of ions directed at a substrate. Ion bursts are used in the ALE processes in this disclosure to remove material in short, highly controlled increments. This method allows for precise control over ion energy and exposure time, reducing unwanted effects like unwanted RIE during the sputtering step.

Tailored Waveform Generator: A device that produces custom waveforms, typically used to control the bias applied to a substrate during processing. The waveform can be designed to precisely modulate the energy and timing of ion acceleration or other processes, ensuring optimal control over etching steps.

Single Gas or Gas Mixture: A gas or combination of gases used throughout a process, such as etching, without requiring changes or exchanges of the gas composition. In the context of the present disclosure, it reduces complexity and improve efficiency of the novel ALE process.

System Controller: A control unit responsible for overseeing and coordinating the various components of a process system. The system controller manages operations such as plasma generation, gas flow, power delivery, substrate biasing, and timing of process steps to ensure optimal performance and process precision.

Switch: A device that controls the connection between different circuit elements. In process systems, a switch may be used to alternate between grounding the substrate and connecting it to other devices, such as waveform generators, to control the electrical potential during different stages of processing.

Plasma Source: A device that generates plasma, a state of matter consisting of charged particles (ions and electrons), as well as neutrals. Plasma sources are used in various manufacturing processes to provide reactive species that can modify surfaces, etch materials, or deposit films.

Etching Selectivity: The ability of an etching process to preferentially remove one material over another. High selectivity ensures that the desired material is removed while leaving other materials intact, which is particularly important in multi-layer structures or devices with delicate features.

Reactive Ion Etching (RIE): A plasma-based etching technique that uses chemically reactive ions to remove material from a substrate. RIE combines physical sputtering with chemical reactions to achieve anisotropic etching, meaning it can etch more vertically than horizontally. It is commonly used in semiconductor fabrication for creating fine, high-precision patterns.

Fluorine-Containing Gases: Gases that contain fluorine atoms, often used in etching processes due to fluorine's high reactivity with many materials. Examples include CF₄ (carbon tetrafluoride), SF₆ (sulfur hexafluoride), and C₂F₆ (hexafluoroethane). Fluorine-containing gases are frequently used for etching silicon-based materials in semiconductor manufacturing.

Pulse Train: A sequence of pulses, used to describe a series of controlled bias voltage for a substrate in a process. In semiconductor processing, a pulse train may be applied to control the timing and energy of ion bombardment, allowing for precise material removal during etching.

Chamber Pressure: The pressure maintained within a process chamber, which can be controlled to optimize various steps in a process, such as plasma generation, etching, or deposition. The chamber pressure can influence the behavior of gases, plasma, and ions, as well as the rate and selectivity of material removal.

Substrate Bias: An electrical potential applied to the substrate during a process, often to control ion acceleration toward the substrate. By adjusting the substrate bias, the energy and direction of incoming ions can be controlled, which is critical for ensuring precise material removal and reducing unwanted effects like damage or over-etching.

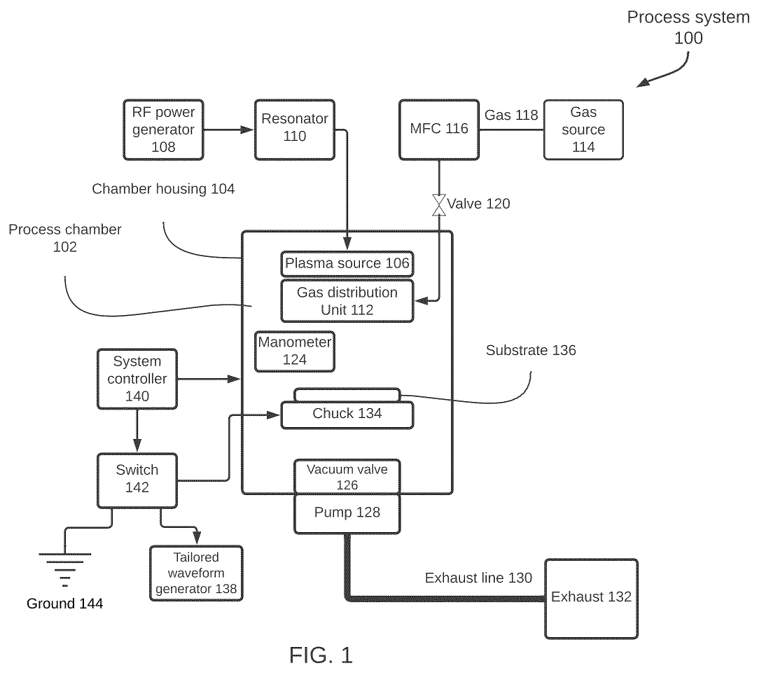

FIG. 1 illustrates an exemplary ALE process system, designated as system 100. This system comprises a process chamber 102, controlled by a system controller 140. The chamber 102 is enclosed by a housing 104, which maintains a vacuum environment conducive to plasma processing. The housing 104, constructed from materials like aluminum or quartz, may have an anodized or yttrium oxide-coated interior to resist plasma damage.

A plasma source 106 is positioned atop the housing 104, separated by a hermetically sealed window, which may be made from materials such as quartz or ceramics. The window's interior can also be coated with a plasma-resistant material like yttrium oxide. The plasma source 106 can be an inductively coupled plasma (ICP) or transformer coupled plasma (TCP) source, with various configurations like cylindrical or conical multiple-turn coils.

The plasma source 106 is powered by an RF power generator 108, connected via a resonator 110. The generator 108 can supply RF power at single or multiple frequencies (e.g., 100 kHz, 200 kHz, 2 MHz, 13.56 MHz, 27 MHz, and 60 MHz), and a power level ranging from 50 watts to 5000 watts. The resonator 110 ensures impedance matching between the generator 108 and the plasma load in chamber 102.

A gas distribution unit 112, connected to a gas source 114 via a mass flow controller (MFC) 116, delivers a gas 118 to the process chamber. A valve 120 controls the flow between the MFC 116 and the gas distribution unit 112. In various embodiments, gas 118 could be a single substance, like chlorine for silicon etching, or a mixture, such as chlorine and argon. For high-aspect-ratio (HAR) structures like channel holes etched through the oxide-nitride-oxide-nitride (ONON) stack used in 3D NAND fabrication, fluorine-containing gases may be utilized. A key aspect of the invention is using a single gas or gas mixture throughout the ALE process, reducing cycle time by eliminating gas exchanges.

The MFC 116 regulates gas flow, and in some configurations, gases may be mixed in a manifold (not shown) before being delivered to the distribution unit 112, which can function as an injector or a showerhead. The window may also integrate with the gas distribution unit 112, serving as a showerhead and sealing the chamber 102. A manometer 124 monitors chamber pressure, while a pump 128 (such as a turbo molecular pump) removes unused gases and byproducts through exhaust line 130 to an exhaust system 132.

A vacuum valve 126 controls gas conductance in tandem with the pump 128. A valve controller, using a proportional-integral-derivative (PID) control, adjusts a movable part of the valve 126 to maintain steady-state chamber pressure as monitored by the system controller 140. The time required to stabilize the position of the movable part can limit ALE process cycle times, particularly during gas exchanges. Therefore, reducing or eliminating the need for gas exchanges enhances process efficiency.

The chamber 102 also includes a chuck 134, which supports the substrate 136. The chuck 134 can be an electrostatic or vacuum chuck, and its bias is crucial for process control. The novel ALE process is characterized by a continuous surface modification step throughout the ALE process without process gas exchanges. During the surface modification step, chemically reactive neutrals from the plasma modify the surface of the substrate continuously, creating a modified surface layer. The novel ALE process is further characterized by multiple intermittent ion-burst sputtering steps, overlapping surface modification steps. During the sputtering steps, a pulse which is a part of a pulse train, generated by a tailored waveform generator 138, is applied to the chuck 134. The pulse includes sequential ion-bursts to remove the modified layer. This step is carefully timed to avoid inducing reactive ion etching (RIE), ensuring the removal of the modified layer without re-modification of the surface.

Between consecutive pulses, the substrate surface is re-modified during the interval. To prevent ion bombardment during the interval, the chuck 134 is grounded via a switch 142, controlled by the system controller 140, preventing the formation of a plasma sheath. A conventional blocking capacitor between the chuck 134 and the ground 144 is eliminated. The switch 142 should be operated at high speed controlled by an electrical signal based on an instruction from the system controller 140. The switch 142 maybe implemented in various forms, which include but are not limited to insulted-gate-bipolar-transistor (IGBT), a power MOSFET, a SiC MOSFET, a GaN transistor, a thyristor, solid-state replay, and a mechanical relay.

Within the pulse, the switch 142 connects the chuck 134 to the tailored waveform generator 138 to apply sequential brief biases of high voltage to accelerate ions in the plasma to deliver ion-burst sputtering. This method ensures rapid bias establishment in microseconds, compared to conventional RF power generators for establishing a steady-state bias, which may require tens of milliseconds.

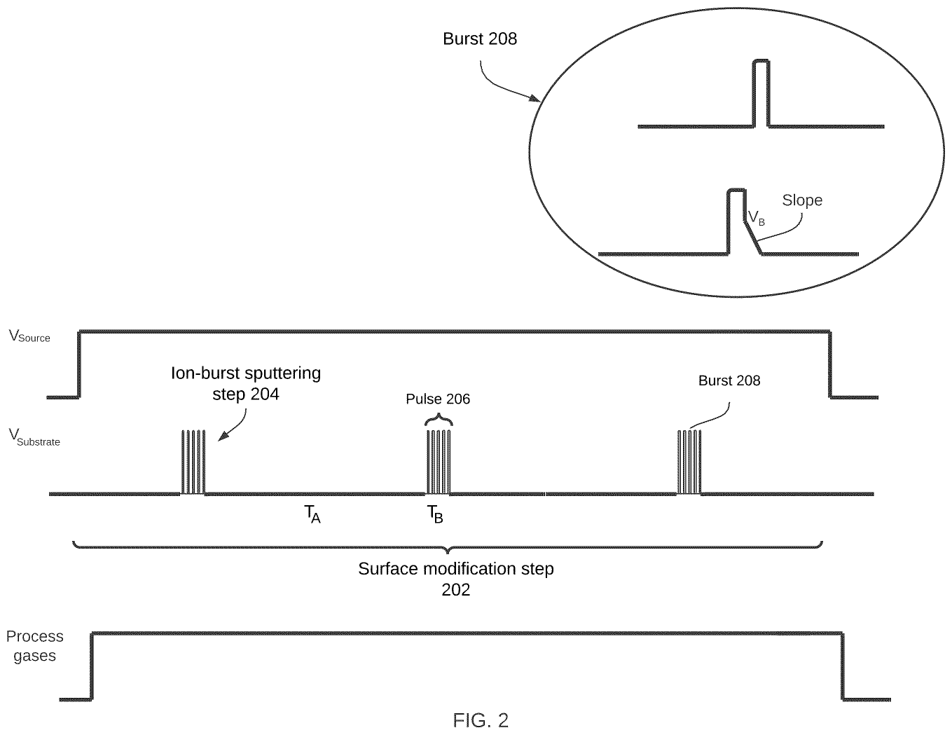

FIG. 2 illustrates exemplary waveforms for the plasma source voltage V_{Source} and substrate bias V_{Substrate}. The flow of either a single gas or a gas mixture is also depicted at the bottom of FIG. 2. As depicted on the top-right part of FIG. 2, the output from the tailored waveform generator begins with a brief positive voltage spike, neutralizing trapped positive charges from the preceding bias by attracting electrons on the substrate. This is followed by a negative bias V_{B}, which ramps down to a more negative voltage, compensating for trapped positive charges from ions. This ramp ensures a constant substrate bias V_{Substrate} for ion acceleration during each of the ion-burst events.

The surface modification duration between two consecutive pulses is T_{A}, while the duration of the pulse in the ion-burst sputtering step is T_{B}. In an ALE process chamber, the gap between the gas distribution unit 112 and the chuck 134 is typically between 3 to 30 centimeters. It takes approximately 20 to 200 milliseconds for neutrals to diffuse from near the plasma source to the substrate 136 held by the chuck 134. According to Karanik et al. in “Atomic Layer Etching: Rethinking the Art of Etch” (J. Phys. Chem Lett. vol. 9, 2018, pp. 4814-4821), surface reactions can take milliseconds to complete. In practical terms, an additional 30 to 300 milliseconds may be required for neutrals to reach and react with the surface atoms, especially at the bottom of high aspect ratio structures. As such, T_{A} is typically set between 50 and 500 milliseconds, depending on chamber volume, plasma density, and structure aspect ratio, while T_{B} is typically ranged between 10 and 50 milliseconds to ensure sufficient ion flux to remove the modified layer while minimizing further surface modification during the ion-burst sputtering.

In this embodiment, surface modification occurs continuously in the background. Since no gas exchanges are required during the ALE process, the neutral concentration inside the chamber 102 remains high, allowing T_{A} to be significantly shorter than in conventional ALE processes, potentially less than 50 milliseconds.

Further, the pulse duration for the sputtering step depends on the ion flux and yield, which is also a function of ion energy. To reduce the pulse duration, either ion density or ion energy can be increased. Therefore, the novel ALE process disclosed herein requires a high ion density and energy to reduce the ion exposure time. The short sputtering time reduces the probability that the surface is re-modified during the sputtering and consequently minimizes unwanted RIE etching during the sputtering.

In FIG. 2, a constant RF power is illustrated throughout the ALE process, where the RF power includes at least one frequency in a range from 100 kHz to 60 MHz, and a power level in a range from 50 watts to 5000 watts.

The RF power can be switched on and off at a predetermined frequency ranging from 100 Hz to 100 kHz, with a duty cycle of 1% to 50%. The RF power during the sputtering step may differ from that during the surface modification process. In some cases, different RF power maybe applied during the sputtering step.

The precise process window for RF power and timing may be determined through an ALE process simulator, considering factors such as gas flow, chamber size, and structure aspect ratios. Alternatively, the parameters may be optimized using design of experiments (DOE) methodologies.

Since a single gas or gas mixture is used throughout the ALE process, chamber pressure must be carefully designed. Higher pressure can reduce surface modification time and increase ion density during the sputtering step, but it can also broaden ion angular distribution, affecting profile accuracy. Ideal chamber pressure ranges from 1 mTorr to 500 mTorr, depending on the specific application.

In an alternative embodiment, chamber pressure may be modulated by the system controller 140 without changing the gas composition. For instance, gas pressure during the sputtering step can be reduced compared to the surface modification step by adjusting the gas flow rate via the MFC 116 or modifying the position of the valve 126.

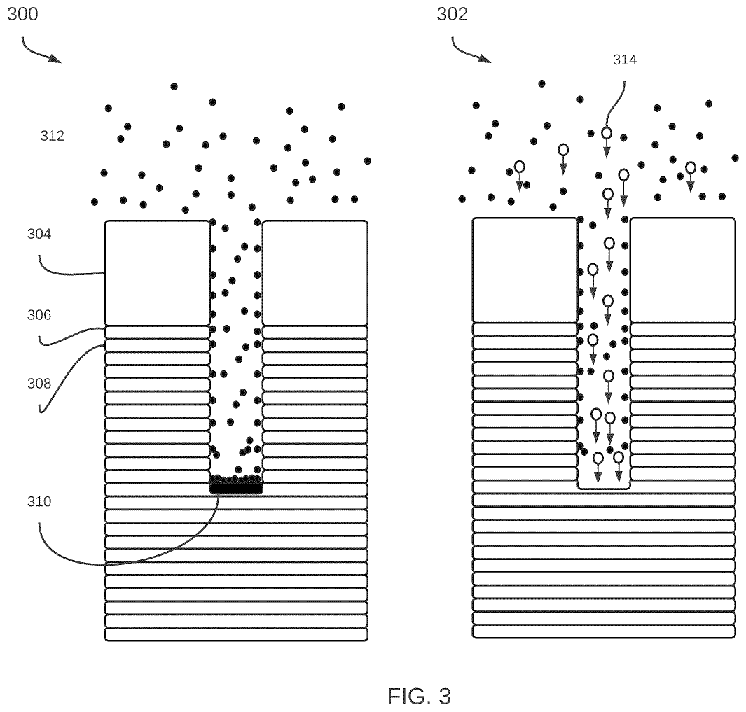

FIG. 3 depicts the application of the ALE process for etching an oxide-nitride-oxide-nitride (ONON) stack to form channel holes in 3D NAND devices. The structure undergoing the surface modification is labeled as 300 and the structure undergoing the ion-burst sputtering as 302. The hard mask is denoted as 304, while the oxide layer and nitride layer are labeled as 306 and 308, respectively. A modified layer 310 forms at the bottom of the structure due to reactions between surface atoms and chemically reactive neutrals 312. For example, fluorine-containing reactive neutrals may diffuse to the etch front, reacting with surface atoms to weaken bonds in the modified layer. When the tailored waveform generator 138 provides burst biases to the chuck, ions 314 are accelerated towards the etch front to sputter away the modified layer. It is essential that the ions have a small angular distribution to maintain vertical profiles for the structure's sidewalls.

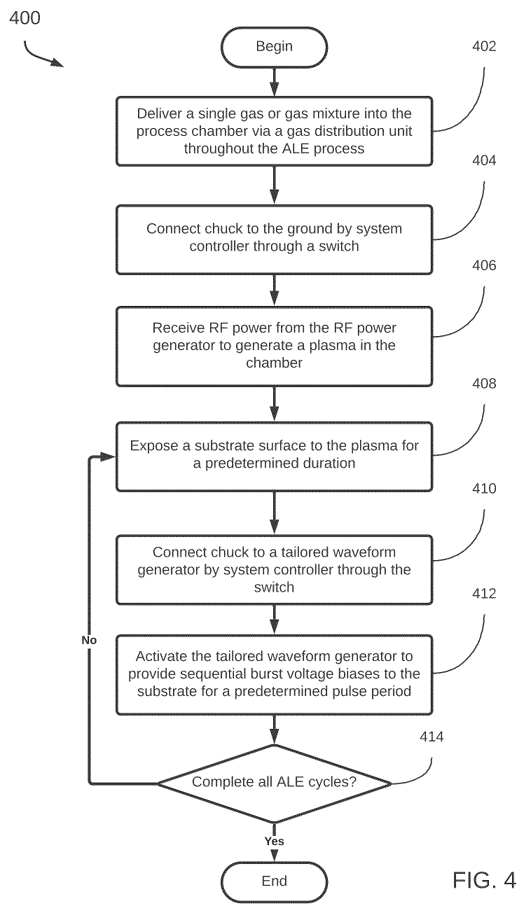

FIG. 4 outlines an exemplary ALE process, labeled as 400. The process begins with step 402, where the system controller 140 introduces a single gas or gas mixture 118 into the chamber 102 via the gas distribution unit 112. For example, fluorine-containing gases may be used for etching channel holes in the ONON stack. In step 404, the system controller 140 initiates an instruction to connect the chuck 134 to the ground 144 through the switch 142.

In step 406, RF power is applied to the plasma source 106 by the RF power generator 108. This power may consist of one or more frequencies between 100 kHz and 60 MHz, with power levels from 50 to 5000 watts. The RF power may be pulsed at a frequency of 100 Hz to 100 kHz with a duty cycle of 1% to 50%, or it may remain constant throughout the modification step.

In step 410, the system controller 140 connects the chuck 134 to the tailored waveform generator 138 via the switch 142. The substrate 136 is exposed to plasma for 50 to 500 milliseconds, sufficiently modifying its surface. During the ion-burst sputtering step in step 412, the tailored waveform generator is activated to provide bias to the substrate for 10 to 50 milliseconds. During the pulse, sequential ion-bursts are generated, ensures that ions, accelerated by the substrate bias, remove the modified layer without giving chemically reactive neutrals enough time to cause further surface modification. The substrate bias may range from 100 to 10,000 volts.

Finally, in step 414, the system controller 140 checks whether all ALE cycles are complete. If not, the steps 404 to 412 are repeated.

1. A process system for performing an ALE process, comprising:
a process chamber configured to maintain a vacuum environment;
a plasma source coupled to an RF power generator configured to generate plasma in the chamber;
a tailored waveform generator for applying a bias to a substrate;
a gas distribution unit configured to receive and supply a single gas, or gas mixture, continuously throughout the ALE process; and
a system controller configured to operate the process system to conduct the ALE process including a surface modification step throughout the ALE process and ion-burst sputtering steps inserted into the surface modification step,
wherein a switch is used by the system controller to connect a chuck to the tailored waveform generator during the sputtering steps and to ground otherwise, and
wherein the duration of the sputtering steps is designed to minimize additional surface modification during the step.

2. The process system of claim 1, wherein each ion-burst sputtering step includes a pulse comprising a plurality of sequential bursts of the bias for the substrate, generated from the tailored waveform generator.

3. The process system of claim 1, wherein the switch consists of a selection from an IGBT, a power MOSFET, a SiC MOSFET, a GaN transistor, a thyristor, solid-state replay, and a mechanical relay.

4. The process system of claim 1, wherein the system controller operates the switch to define an interval between the two consecutive sputtering steps with a duration ranging from 50 to 500 milliseconds and define the duration of the sputtering step ranging from 10 to 50 milliseconds.

5. The process system of claim 1, wherein the system controller utilizes an ALE process simulator to determine an interval between two consecutive sputtering steps and the duration of the sputtering steps, such that the substrate surface is sufficiently modified during the interval, while the modification within the sputtering step is minimized.

6. The process system of claim 1, wherein the tailored waveform generator provides voltage biases for the substrate in a range from 100 to 10,000 volts during the sputtering step.

7. The process system of claim 1, wherein the plasma source is further configured to receive RF power from the RF power generator with pulsing at a predetermined frequency ranging from 100 Hz to 100 kHz, and at a duty cycle from 1% to 50% during the surface modification step.

8. The process system of claim 1, wherein the plasma source is further configured to receive RF power, during the ion-burst sputtering steps, at a higher power level than the RF power received between the sputtering steps.

9. The process system of claim 1, wherein the controller further operates the chamber at a pressure level in a range from 1 mTorr to 500 mTorr.

10. The process system of claim 1, wherein the single gas or gas mixture further include carbon and fluorine-based species.

11. The process system of claim 1, wherein the process system is utilized to etch high aspect ratio channel holes for 3D NAND devices.

12. A method for conducting an ALE process in a process system comprising a plasma process chamber, the method executed by a system controller including:
a) introducing a gas or gas mixture into the chamber via a gas distribution unit connected to a gas source throughout the ALE process;
b) operating a switch to connect a chuck to ground;
c) generating plasma in the chamber by applying RF power to a plasma source from an RF power generator;
d) subjecting a substrate surface to the plasma for a duration ranging from 50 to 500 milliseconds to form a modified surface layer;
e) operating the switch to connect the chuck to a tailored waveform generator;
f) subjecting the substrate surface to ions to remove the modified layer for a period ranging from 10 to 50 milliseconds, wherein the ions are accelerated by a plurality of sequential voltage biases generated by the tailored waveform generator; and
g) repeating steps b) to f) until the completion of the ALE process, wherein the gas or gas mixture remain unchanged throughout the ALE process.

13. The method of claim 12, wherein, in step f), the tailored waveform generator establishes the biases ranging from 100 to 10,000 volts.

14. The method of claim 12, wherein, in step c), the plasma source is configured to receive continuous RF power from the RF power generator, where the RF power includes at least one frequency ranging from 100 kHz to 60 MHz, and a power level ranging from 50 watts to 5000 watts.

15. The method of claim 12, wherein, in step c), the plasma source is adapted to receive pulsed RF power from the RF power generator at a predetermined frequency from 100 Hz to 100 kHz, with a duty cycle ranging from 1% to 50%.

16. The method of claim 12, wherein step f) additionally involves the plasma source receiving RF power from the RF power generator, at a different power level than the power applied in step c).

17. The method of claim 12, further comprising a step of regulating the chamber pressure to a steady state ranging from 1 mTorr to 500 mTorr, as controlled by the system controller based on readings from a manometer.

18. The method of claim 12, wherein the gas or gas mixture used in the process include at least one halogen.

19. The method of claim 12, wherein the switch consists of a selection from an IGBT, a power MOSFET, a SiC MOSFET, a GaN transistor, a thyristor, solid-state replay, and a mechanical relay.

20. The method of claim 12, wherein the method is utilized to etch high aspect ratio channel holes for 3D NAND devices.
